(19) United States
(12) Patent Application Publication
(10) Pub. No.: US 2015/0075593 A1
(43) Pub. Date: Mar. 19, 2015

(54) SOLAR LIGHT-RADIOISOTOPE HYBRID BATTERY

(71) Applicant: Electronics and Telecommunications Research Institute, Daejeon (KR)

(72) Inventors: Byoung-Gun CHOI, Daejeon (KR); Sung-Weon KANG, Daejeon (KR); Kyung-Hwan PARK, Daejeon (KR); Kwang-Jae SON, Sejong (KR)

(21) Appl. No.: 14/448,423

(22) Filed: Jul. 31, 2014

(30) Foreign Application Priority Data
Sep. 16, 2013 (KR) 10-2013-0111172

(51) Int. Cl. G21H 1/06; H01L 31/04

(52) U.S. Cl. CPC G21H 1/06; H01L 31/04
USPC 136/252; 310/303

(57) ABSTRACT

Disclosed herein is a solar light-radioisotope hybrid battery, which is used as a solar battery and a radioisotope battery when sunlight is applied, and is used as a radioisotope battery when sunlight is not applied. The solar light-radioisotope hybrid battery includes: a semiconductor layer producing an electron-hole pair; and a radioisotope layer formed on the semiconductor layer and emitting a radioactive ray to the semiconductor layer.

### CROSS REFERENCE TO RELATED APPLICATION

This application claims the benefit of Korean Patent Application No. 10-2013-0111172, filed on Sep. 16, 2013, which is hereby incorporated by reference in its entirety into this application.

### BACKGROUND OF THE INVENTION

1. Technical Field

The present invention relates to a solar light-radioisotope hybrid battery, and, more particularly, to a solar light-radioisotope hybrid battery capable of being used as a power source for artificial satellites and space probes.

2. Description of the Related Art

Artificial satellites running in the atmosphere of the Earth are equipped with solar cell panels to produce electric power. When an artificial satellite is located at the position that is opposite to the Earth with respect to the Sun, it cannot absorb solar light, thus not producing electric power. Therefore, this artificial satellite must use the electric power charged during the day, and, otherwise, may be restricted in operation.

Solar batteries of space probes for exploring the Moon and planets in the Solar system absorb solar light to charge electric power or use the charged electric power during the day, but they cannot function as solar batteries during the night. Particularly, in the case of Moon probes, technologies for producing electric power during the night are required because the night of the Moon is long (about 14 days).

As such, the solar battery used as a power source for artificial satellites or space probes does not function as a solar battery when sunlight is blocked.

As a related art, U.S. Pat. No. 7,939,986 discloses a betavoltaic cell for producing electric power from beta radiation using a SiC substrate having a high aspect ratio.

The betavoltaic cell disclosed in U.S. Pat. No. 7,939,986 has a high aspect ratio structure for increasing energy conversion efficiency, and is configured such that a trench-shaped PN junction surface is formed by a deep reactive ion etching (DRIE) process, and is then directly deposited with a radioisotope.

The above-mentioned betavoltaic cell disclosed in U.S. Pat. No. 7,939,986 uses only radioactive rays as an energy source, and does not use both solar light and radioactive rays simultaneously.

As another related art, U.S. Pat. No. 5,606,213 discloses a nuclear battery configured such that a semiconductor itself emits beta rays using tritiated amorphous silicon PN junction, and electric power is produced by the emitted beta rays.

The nuclear battery disclosed in U.S. Pat. No. 5,606,213 is configured such that a depletion layer of tritiated amorphous silicon PN junction absorbs beta rays to produce electric current, semiconductor contains a radioisotope, and an isotope battery can be manufactured only by a semiconductor process.

The above-mentioned nuclear battery disclosed in U.S. Pat. No. 5,606,213 also does not use both solar light and radioactive rays simultaneously.

### SUMMARY OF THE INVENTION

Accordingly, the present invention has been made to solve the above-mentioned problems, and an object of the present invention is to provide a solar light-radioisotope hybrid battery, which is used as a solar battery and a radioisotope battery when sunlight is applied, and is used as a radioisotope battery when the sunlight is not applied.

In order to accomplish the above object, an aspect of the present invention provides a solar light-radioisotope hybrid battery, including: a semiconductor layer producing an electron-hole pair; and a radioisotope layer formed on the semiconductor layer and emitting a radioactive ray to the semiconductor layer.

Preferably, the semiconductor layer may absorb photons incident from the sun to produce the electron-hole pair, and may absorb a radioactive ray emitted from the radioisotope layer to produce the electron-hole pair.

Preferably, the radioactive ray may be one of alpha ray, beta ray and gamma ray, and the radioisotope layer may include a nuclide emitting the radioactive ray.

Preferably, the radioisotope layer may adhere closely to one side of the semiconductor layer.

Preferably, the radioisotope layer may adhere to one side of the semiconductor layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic view showing a solar light-radioisotope hybrid battery according to an embodiment of the present invention.

FIG. 2 is a schematic view explaining the action of a solar light-radioisotope hybrid battery according to an embodiment of the present invention.

### DESCRIPTION OF THE PREFERRED EMBODIMENTS

The present invention may be embodied in many different forms without departing from the spirit and significant characteristics of the invention. Therefore, the embodiments of the present invention are disclosed only for illustrative purposes and should not be construed as limiting the present invention.

However, it will be understood that the present invention is not limited to specific embodiments, and includes all modifications, equivalents and alternatives included in the idea and technical scope of the invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, preferred embodiments of the present invention will be described in detail with reference to the attached drawings. Throughout the accompanying drawings, the same reference numerals are used to designate the same or similar components, and redundant descriptions thereof are omitted.

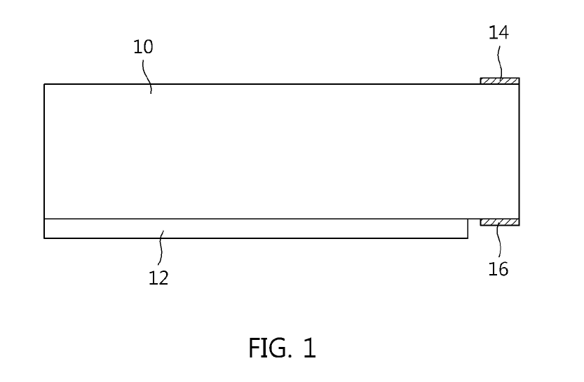

FIG. 1 is a schematic view showing a solar light-radioisotope hybrid battery according to an embodiment of the present invention.

As shown in FIG. 1, the solar light-radioisotope hybrid battery according to an embodiment of the present invention includes a semiconductor layer 10, a radioisotope layer 12 and electrodes 14 and 16.

The semiconductor layer 10 produces an electron-hole pair. The semiconductor layer 10 may be composed of a PN junction semiconductor.

Preferably, the semiconductor layer 10 may absorb photons (particles of light) incident from the sun to produce an electron-hole pair. Meanwhile, the semiconductor layer 10 may absorb a radioactive ray emitted from the radioisotope layer 12 to produce an electron-hole pair.

The radioisotope layer 12 emits a predetermined radioactive ray to the semiconductor layer 10. Here, the radioactive ray is one of alpha ray, beta ray and gamma ray. Thus, the radioisotope layer 12 includes a nuclide emitting the radioactive ray. For example, among radioisotopes, Ni, Pm, Sr or the like emits a pure beta ray of radioactive rays. When this radioisotope layer 12 is attached to a solar battery, the beta ray emitted from the radioisotope produces an electron-hole pair, similarly to when photons are incident onto the solar battery. The produced electron-hole pair generates electric current to serve as a solar battery. The beta ray, which is a flow of electrons (beta particles), is relatively safe compared to alpha ray or gamma ray because it can be blocked only by a sheet of paper. Further, the beta ray is a radioactive layer capable of generating electric power without damaging a semiconductor grating. Further, since the life time of a radioisotope emitting a beta ray is proportional to a half life, this radioisotope can be semi-permanently used for several tens˜several hundreds of years.

The radioisotope layer 12 is formed on the semiconductor layer 10. For example, the radioisotope layer 12 may be formed on any one of top, bottom and flank In this case, the radioisotope layer 12 adheres closely to the semiconductor layer 10 by coating one side of the semiconductor layer 10 with a radioisotope through deposition, plating or the like. Meanwhile, although not shown, in order to accelerate the formation of the radioisotope layer 12, a seed layer is formed on one side of the semiconductor layer 10, and then the radioisotope layer 12 is formed on the seed layer.

Alternatively, the radioisotope layer 12 may be formed by adhering or sticking a radioisotope to any one of top, bottom and flank of the semiconductor layer 10 in the form of a sealed source or a non-sealed source.

If necessary, the radioisotope layer 12 may be formed in the semiconductor layer 10, not on the top, bottom or flank of the semiconductor layer 10.

The electrode 14 is formed on one side of the semiconductor layer 10, and the electrode 16 is formed on a side opposite to one side. For example, the electrode 14 may be used as a cathode, and the electrode 16 may be used as an anode. Of course, conversely, the electrode 14 may be used as an anode, and the electrode 16 may be used as a cathode. As shown FIG. 1, one side of the semiconductor 10 is provided with both the radioisotope layer 12 and the electrode 16. In this case, it is preferred that the radioisotope layer 12 and the electrode 16 be spaced apart from each other for the purpose of insulation.

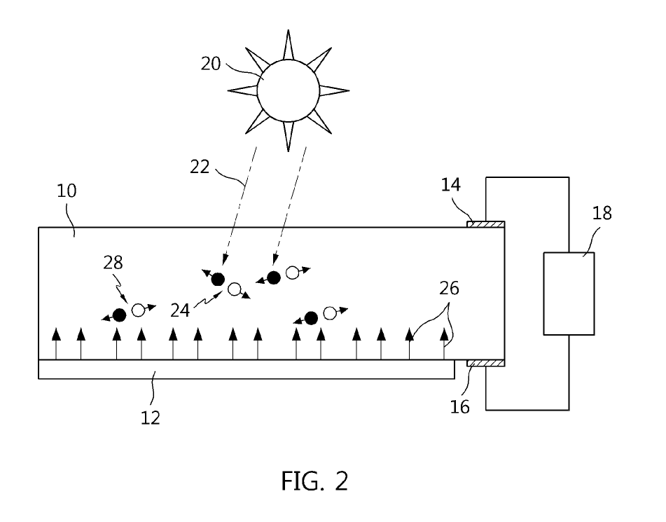

FIG. 2 is a schematic view explaining the action of a solar light-radioisotope hybrid battery according to an embodiment of the present invention.

When the solar light-radioisotope hybrid battery according to an embodiment of the present invention is located at the place, to which solar light is applied, the semiconductor layer 10 absorbs photons 22 incident from the sun 20 to produce an electron-hole pair 24, thus contributing to the generation of photocurrent of the battery. Further, the semiconductor layer 10 absorbs radioactive rays 26 emitted from the radioisotope of the radioisotope layer 12 to produce an electron-hole pair 28, thus contributing to the generation of output current of the battery. Here, the radioactive rays are classified into alpha ray, beta ray and gamma according to the kind of nuclides. The reference numeral “18” indicates a load connected to the electrodes 14 and 16.

Of course, when the solar light-radioisotope hybrid battery according to an embodiment of the present invention is located at the place, to which solar light is not applied, the semiconductor layer 10 absorbs the radioactive rays 26 emitted from the radioisotope of the radioisotope layer 12 to produce an electron-hole pair 28, thus contributing to the generation of output current of the battery.

As described above, the solar light-radioisotope hybrid battery according to an embodiment of the present invention includes the semiconductor layer coated on one side thereof with a radioisotope. Therefore, this hybrid battery can produce electric power as a solar battery and a radioisotope battery when solar light exists, and can be used as a radioisotope battery for producing electric power by absorbing the radioactive rays emitted from a radioisotope when solar light does not exist.

According to the solar light-radioisotope hybrid battery of the present invention, electric power can be generated even at the place at which the sunlight is blocked.

Meanwhile, in the case of the exploration of a planet (Mars, Jupiter, Saturn or the like) remote from the sun, the intensity of solar light is rapidly reduced. Therefore, when the solar light-radioisotope hybrid battery of the present invention is used in this case, electric power can be generated by radioisotope and solar light without the need of additional space and weight other than the area of solar cell panel.

Further, as the half life of a radioisotope increases, radioactive rays are emitted for a long time. Therefore, when a radioisotope having a long half life is used, this radioisotope can be semi-permanently used for several tens˜several hundreds of years.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A solar light-radioisotope hybrid battery, comprising:
a semiconductor layer producing an electron-hole pair; and
a radioisotope layer formed on the semiconductor layer and emitting a radioactive ray to the semiconductor layer.

2. The solar light-radioisotope hybrid battery of claim 1, wherein the semiconductor layer absorbs photons incident from the sun to produce the electron-hole pair, and absorbs a radioactive ray emitted from the radioisotope layer to produce the electron-hole pair.

3. The solar light-radioisotope hybrid battery of claim 1, wherein the radioactive ray is one of alpha ray, beta ray and gamma ray, and the radioisotope layer includes a nuclide emitting the radioactive ray.

4. The solar light-radioisotope hybrid battery of claim 1, wherein the radioisotope layer adheres closely to one side of the semiconductor layer.

5. The solar light-radioisotope hybrid battery of claim 1, wherein the radioisotope layer adheres to one side of the semiconductor layer.

6. A solar light-radioisotope hybrid battery, which absorbs photons incident from the sun to produce an electron-hole pair, and absorbs a radioactive ray emitted from a radioisotope to produce an electron-hole pair.
